(19) United States
(12) Patent Application Publication
(10) Pub. No.: US 2016/0254241 A1
(43) Pub. Date: Sep. 1, 2016

(54) PRINTED CIRCUIT BOARD AND SOLDERING METHOD

(71) Applicant: FUJITSU LIMITED, Kawasaki-shi (JP)

(72) Inventors: Yoshinobu MAENO, Yokohama (JP); Kinuko MISHIRO, Kawasaki (JP)

(73) Assignee: FUJITSU LIMITED, Kawasaki-shi (JP)

(21) Appl. No.: 15/007,663

(22) Filed: Jan. 27, 2016

(30) Foreign Application Priority Data
Feb. 27, 2015 (JP) 2015-038228

(51) Int. Cl. H01L 23/00; H01L 23/498

(52) U.S. Cl. CPC H01L 24/16; H01L 24/81; H01L 23/49838; H01L 2224/16227; H01L 2924/15313; H01L 2224/81801; H01L 2224/812

(57) ABSTRACT

A printed circuit board includes: a substrate; a first electrode formed on the substrate; a protrusion member formed on the first electrode and extending from a central portion of the first electrode towards an outer peripheral portion of the first electrode; and a solder covering the first electrode and the protrusion member and connecting the first electrode to a second electrode of a component mounted on the substrate.

### CROSS-REFERENCE TO RELATED APPLICATION

This application is based upon and claims the benefit of priority of the prior Japanese Patent Application No. 2015-038228, filed on Feb. 27, 2015, the entire contents of which are incorporated herein by reference.

### FIELD

The embodiments discussed herein are related to a printed circuit board and a soldering method.

### BACKGROUND

In order to comply with a demand for miniaturization and thickness reduction of electronic components mounted on an electronic device, increasing of pins, narrowing of a pin pitch, and lowering of a profile in electronic components are progressed. The number of bottom electronic components, which include functional features mounted on a small substrate with high density, is increasing. The bottom electronic components refer to electronic components that include electrodes provided on the bottom surface of a substrate.

As described above, a progressing for a miniaturization, a weight reduction, and a performance enhancement of electronic devices is underway. A LGA (Land Grid Array) semiconductor package, which is a kind of electronic component, enables high density mounting on a printed circuit board and coping with the increase of pins accompanying the performance enhancement. The LGA semiconductor package includes lands (electrodes) arranged in a lattice form on the rear surface of a substrate on which a semiconductor chip such as, for example, an LSI chip, is mounted. The LGA semiconductor package does not have a ball-shaped solder (solder ball), and thus contributes to thickness reduction of semiconductor packages.

When an electronic component is mounted on a printed circuit board, for example, by soldering, the solder is solidified in a state where a gas generated by vaporization of flux contained in the solder paste remains in the solder so that voids are generated within the solder. The number, locations, sizes, or the like of voids vary widely. FIGS. 15 to 17 illustrate examples of voids generated within the solder. FIGS. 15 to 17 illustrate a printed circuit board 31 and an electronic component 41 mounted on the printed circuit board 31. A pad 32 is formed on the printed circuit board 31. The pad 32 is an electrode used for connection to the electronic component 41. An electrode 42 is formed on the electronic component 41. The electrode 42 is used for connection to the printed circuit board 31. A solder 33 is formed between the pad 32 and the electrode 42 to bond the pad 32 and the electrode 42 to one another.

As illustrated in FIG. 15, a plurality of voids 34 is generated within the solder 33. As illustrated in FIG. 16, a plurality of voids 34 are generated within the solder 33 and one of the voids 34 protrudes outward from the pad 32. Around the void 34 protruding outward from the pad 32, a thin solder film exists. As illustrated in FIG. 17, a plurality of voids 34 are generated within the solder 33 and one of the voids 34 breaks through the solder film and disappears.

When the voids are generated within the solder, an electric characteristic and a heat radiation characteristic are not stable in the bonding portion between the electronic component and the printed circuit board. Also, when large voids are generated within the solder, a positional deviation of an electronic component is caused when the electronic component is mounted on the printed circuit board. When the voids are generated within the solder, a short circuit occurs between adjacent pads or a short circuit occurs between adjacent electrodes.

The followings are reference documents.

[Document 1] Japanese Laid-Open Patent Publication No. 2008-311417,

[Document 2] Japanese Laid-Open Patent Publication No. 09-074267,

[Document 3] Japanese Laid-Open Patent Publication No. 2005-142497,

[Document 4] Japanese Laid-Open Patent Publication No. 2004-095864, and

[Document 5] Japanese Laid-Open Patent. Publication No. 2005-303079.

### SUMMARY

According to an aspect of the invention, a printed circuit board includes: a substrate; a first electrode formed on the substrate; a protrusion member formed on the first electrode and extending from a central portion of the first electrode towards an outer peripheral portion of the first electrode; and a solder covering the first electrode and the protrusion member and connecting the first electrode to a second electrode of a component mounted on the substrate.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 is a top view illustrating a portion of a printed circuit board;

FIG. 2A is a sectional view illustrating a section taken along line A1-A2 of FIG. 1 when viewed in the direction indicated by arrows;

FIG. 2B is a sectional view illustrating a section taken along line B1-B2 of FIG. 1 when viewed in the direction indicated by arrows;

FIG. 3 is a sectional view illustrating a portion of a printed circuit board on which an electronic component is mounted;

FIG. 4 is a top view illustrating a portion of a printed circuit board;

FIG. 5 is a diagram illustrating a process of a soldering method;

FIG. 6 is a diagram illustrating a process of the soldering method;

FIG. 7 is a diagram illustrating a process of the soldering method;

FIG. 8 is a diagram illustrating a process of the soldering method;

FIG. 9 is an explanatory view illustrating a mechanism of suppressing void generation;

FIG. 10 is an explanatory view illustrating a mechanism of suppressing void generation;

FIG. 11 is an explanatory view illustrating ting a mechanism of suppressing void generation;

FIG. 12 is a top view illustrating a portion of a printed circuit board;

FIG. 13 is a view illustrating an exemplary arrangement of a pad and a protrusion member;

FIG. 14 is a view illustrating an exemplary arrangement of a pad and a protrusion member;

FIG. 15 is a view illustrating an example of voids generated in solder;

FIG. 16 is a view illustrating an example of voids generated in solder; and

FIG. 17 is a view illustrating an example of voids generated in solder.

### DESCRIPTION OF EMBODIMENTS

Hereinafter, descriptions will be made on a printed circuit board and a soldering method according to an exemplary embodiment with reference to the accompanying drawings. The constitution of the exemplary embodiment illustrated in the following is illustrative and the constitution of the present disclosure is not limited to the constitution of the exemplary embodiment.

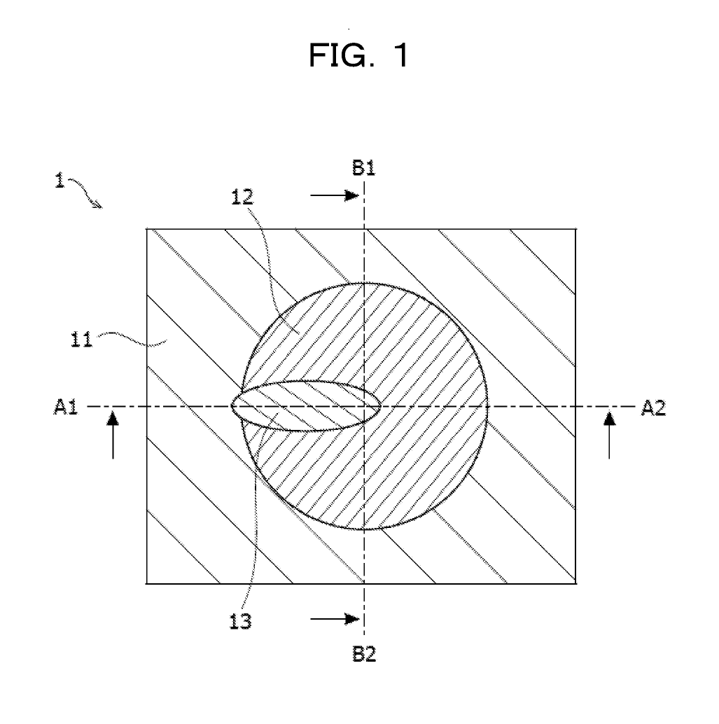

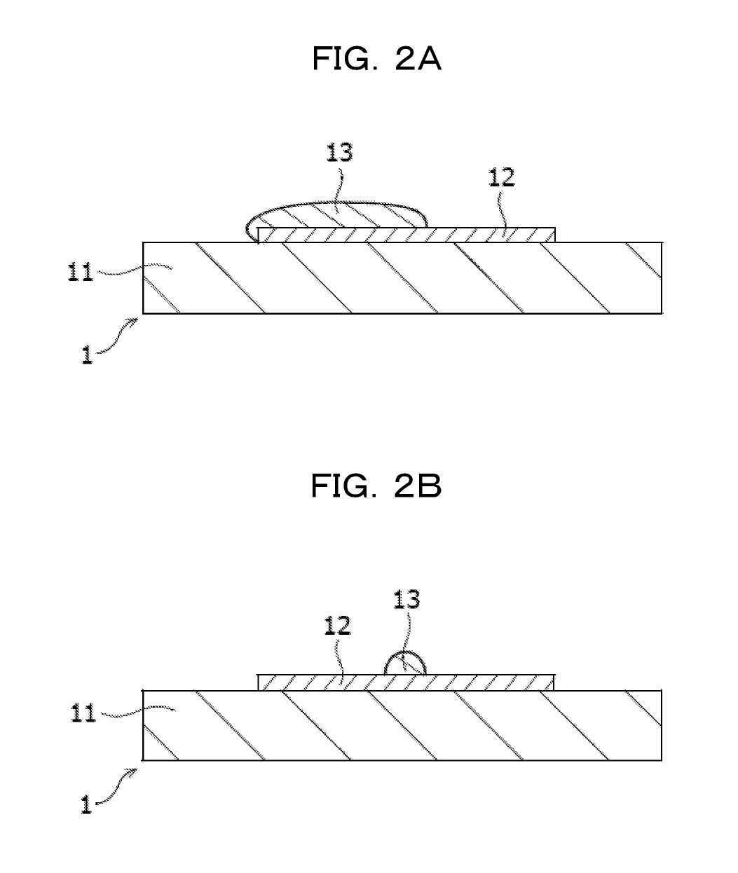

A printed circuit board 1 according to an exemplary embodiment will be described. FIG. 1 is a top view illustrating a portion of the printed circuit board 1. FIG. 2A is a sectional view illustrating a section taken along line A1-A2 of FIG. 1 when viewed in a direction of indicated by arrows. FIG. 2B is a sectional view illustrating a section taken along line B1-B2 of FIG. 1 when viewed in a direction indicated by arrows.

The printed circuit board 1 includes a substrate 11 and a pad 12 formed on the substrate 11. The substrate 11 is, for example, a multilayer substrate in which a plurality of wiring layers (conductor layers) and resin layers are laminated. The substrate 11 is an example of a first substrate. The pad 12 is an electrode used for interconnecting the substrate 11 and an electronic component mounted on the substrate 11. The pad 12 is an example of a first electrode. Although the appearance (shape) of the pad 12 illustrated in FIG. 1 has a perfect circular shape in a plan view, the appearance may have an oval or rectangular shape in the plan view. A material for the pad 12 is, for example, copper (Cu).

A protrusion member 13 is formed on the pad 12. The protrusion member 13 protrudes from the top surface of the pad 12. The protrusion member 13 extends from a central portion of the pad 12 towards an outer peripheral portion of the pad 12. In the case where the appearance of the pad 12 has a perfect circular shape in the plan view, the central portion of the pad 12 refers to the center of the perfect circle, or the center of the perfect circle and a portion around the center. In the case where the appearance of the pad 12 has an oval shape in the plan view, the central portion of the pad 12 refers to the center of the oval shape, or the center of the oval shape and a portion around the center. In the case where the appearance of the pad 12 has a rectangular shape, the central portion of the pad 12 refers to the center of the rectangular shape, or the center of the rectangular shape and a portion around the center. The outer peripheral portion of the pad 12 refers to the boundary portion between the top side and the lateral sides of the pad 12, or the boundary portion between the top side and the lateral sides of the pad 12 and a portion around the boundary portion.

The protrusion member 13 is formed on the pad 12 to cover a portion of the pad 12. One end (first end) of the protrusion member 13 overlaps with the central portion of the pad 12 in the plan view, and the other end (second end) of the protrusion member 13 overlaps with the outer peripheral portion of the pad 12 in the plan view. As illustrated in FIG. 1, the second end of the protrusion member 13 may protrude outwardly from the pad 12 in the plan view.

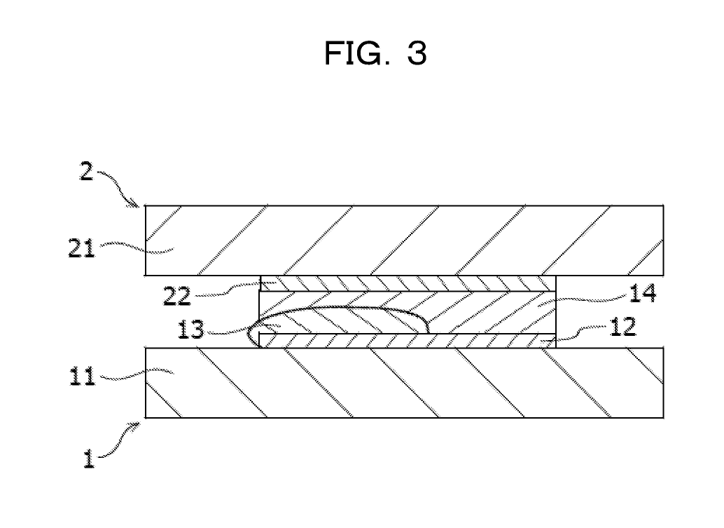

FIG. 3 is a sectional view illustrating a portion of the printed circuit board 1 on which an electronic component 2 is mounted. The electronic component 2 is, for example, an LGA semiconductor package. The electronic component 2 is an example of a component. The electronic component 2 includes a substrate 21 and an electrode 22. The substrate 21 is arranged to be opposite to the substrate 11. The substrate 21 is, for example, a package substrate. The substrate 21 is an example of a second substrate. The electrode 22 is formed on the bottom surface of the substrate 21. The electrode 22 is used for interconnecting the electronic component 2 and the substrate 11 and called a land. The electrode 22 is an example of a second electrode.

Between the pad 12 on the printed circuit board 1 and the electrode 22 on the electronic component 2, a solder 14 is formed to bond the pad 12 and the electrode 22 to one another. The printed circuit board 1 and the electronic component 2 are electrically connected to each other via the solder 14. The solder 14 covers the pad 12 and the protrusion member 13. The pad 12 is bonded to the solder 14, and the electrode 22 is bonded to the solder 14. Therefore, the pad 12 is soldered to the electrode 22 via the solder 14. The protrusion member 13 is in contact with the solder 14. However, the protrusion member 13 is not bonded to the solder 14.

Since the pad 12 includes the protrusion member 13, when the pad 12 and the electrode 22 are soldered to each other via the solder 14, the gas generated within the solder 14 is discharged to the outside from the solder 14 and the generation of voids in the solder 14 is suppressed.

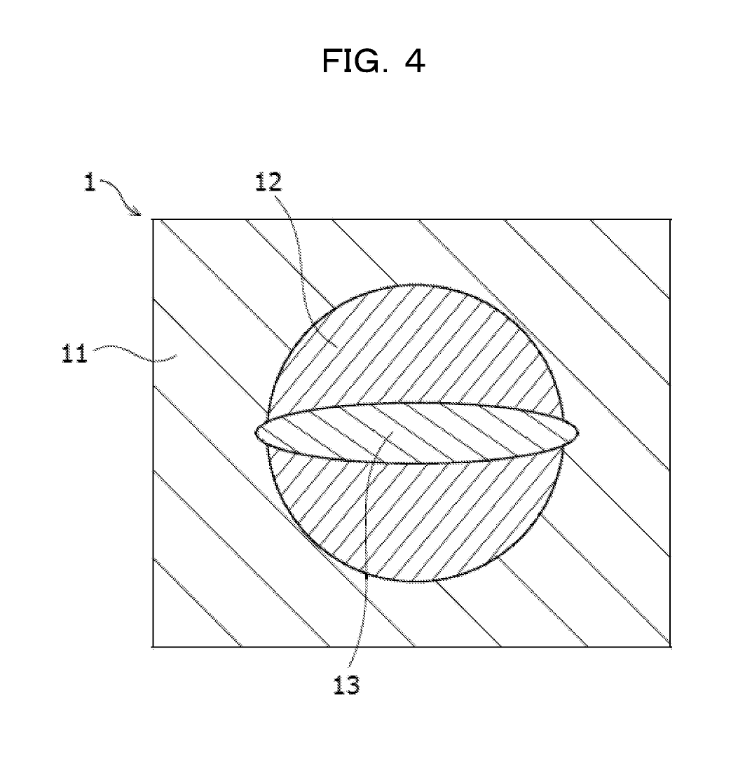

The length of the protrusion member 13 illustrated in FIGS. 1 to 3 (the width in the longitudinal direction) is smaller than the diameter of the pad 12 and longer than the radius of the pad 12. The length of the protrusion member 13 is not limited to that illustrated in FIGS. 1 to 3, and as illustrated in FIG. 4, the length of the protrusion member 13 may be longer than the diameter of the pad 12. FIG. 4 is a top view illustrating a portion of the printed circuit board 1. Both ends of the protrusion member 13 overlap with the outer peripheral portion of the pad 12 in the plan view, and the central portion of the protrusion member overlaps with the central portion of the pad in the plan view. As illustrated in FIG. 4, both ends of the protrusion member 13 may protrude out of the pad 12 in the plan view.

### Soldering Method

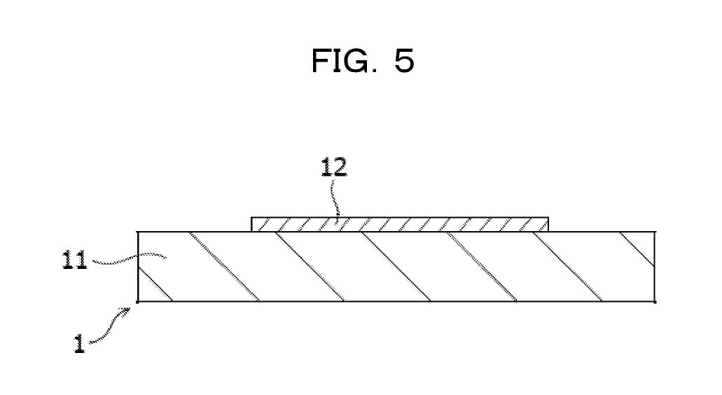

A soldering method will be described with reference to FIGS. 5 to 8. The soldering method may be used as a part of a method for manufacturing the printed circuit board 1, or may be used as a part of a method for mounting the electronic component 2 on the printed circuit board 1. FIGS. 5 to 8 are diagrams illustrating processes of the soldering method. FIGS. 5 to 8 correspond to the section taken along line B1-B2 of FIG. 1. First, the printed circuit board 1 is provided as illustrated in FIG. 5. A pad 12 is formed on a substrate 11 provided in the printed circuit board 1.

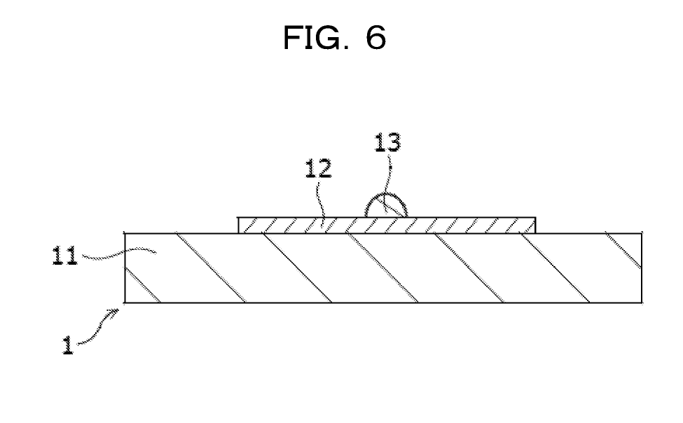

Next, as illustrated in FIG. 6, a protrusion member 13 is formed on the pad 12. The material of the protrusion member 13 is a material that is not bonded to solder or a material that is hardly bonded to solder. The material of the protrusion member 13 may be a material that is not changed at the melting temperature of the solder. The protrusion member 13 may be formed on the pad 12 by supplying a liquid material on the pad 12 and then curing the liquid material. The method for supplying the liquid material may be, for example, a printing method, a transfer method, a dispensing method, or a drawing method. As the protrusion member 13, a fixative and adhesive material may be formed on the pad 12.

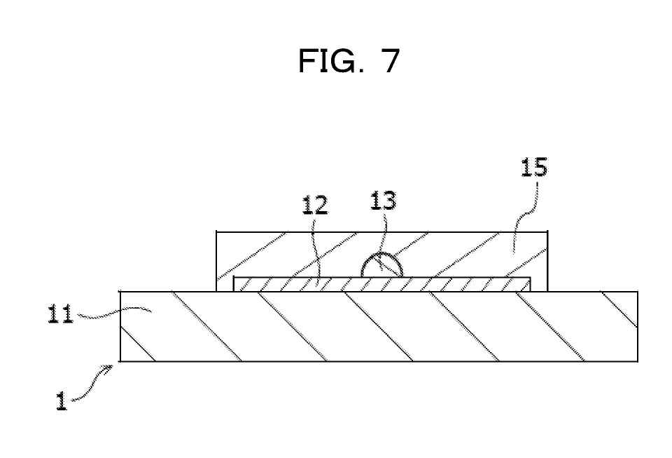

Subsequently, as illustrated in FIG. 7, a solder paste 15 is applied (formed) on the pad 12 and the protrusion member 13 by, for example, a printing method. The solder paste 15 includes solder powder and flux. The solder powder includes, for example, Sn—Ag or Sn—Ag—Cu.

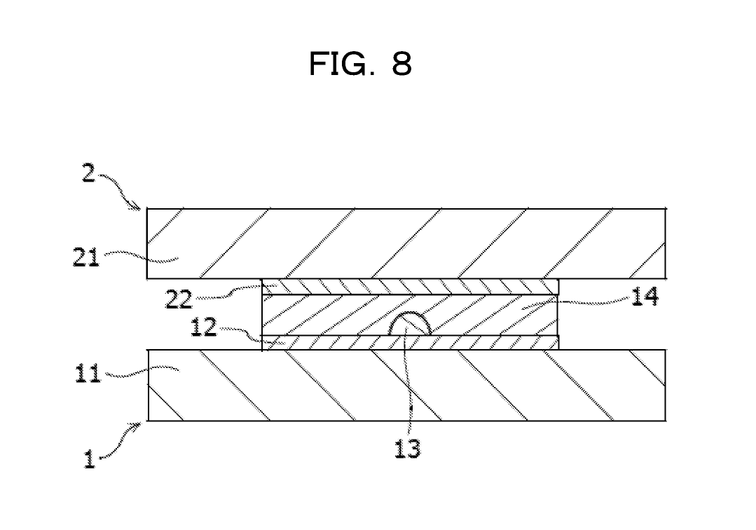

Next, the printed circuit board 1 and the electronic component 2 are aligned and then the electronic component 2 is mounted on the substrate 11. As a result, the electrode 22 of the electronic component 2 comes in contact with the solder paste 15. Subsequently, as illustrated in FIG. 8, by performing a reflow process, the solder 14 is formed between the pad 12 and the electrode 22 so that the pad 12 and the solder 14 are bonded to each other and the solder 14 and the electrode 22 are bonded to each other. As a result, the pad 12 and the electrode 22 are soldered to each other. For example, heating is performed by introducing the printed circuit board 1 and the electronic component 2 into a reflow oven, and cooling is performed by taking out the printed circuit board 1 and the electronic component 2 from the reflow oven. As the heating is performed, the solder powder in the solder paste 15 is molten and the flux in the solder paste 15 is vaporized. As the cooling is performed, the solder 14 is formed between the pad 12 and the electrode 22 so that the pad 12 and the electrode 22 are soldered to each other.

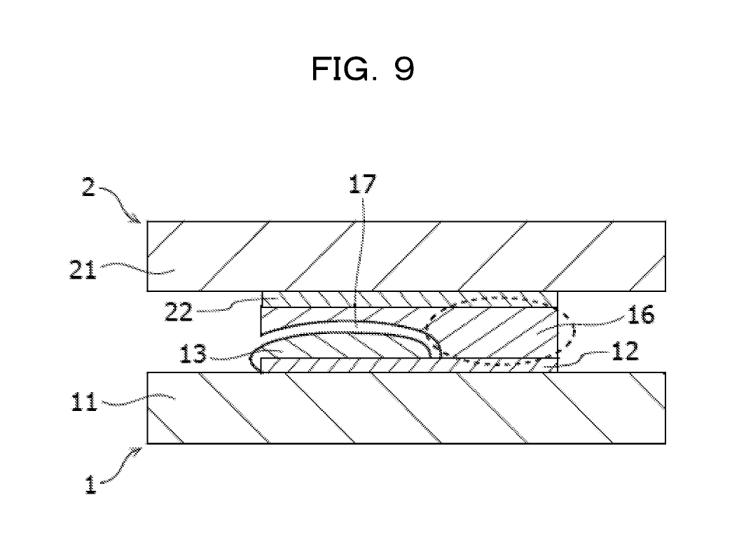

FIGS. 9 to 11 are explanatory views each illustrating a mechanism of suppressing void generation. FIG. 9 illustrates an initial status of a soldering process (reflow process). As illustrated in FIG. 9, the solder paste 15 is heated and the solder powder in the solder paste 15 is molten so that the solder paste 15 becomes a molten solder 16 and the flux in the solder paste 15 is vaporized to generate a gas. Due to the gas residing in the molten solder 16, a void 17 is generated in the molten solder 16. The protrusion member 13 has poor wettability to the molten solder 16, and the pad 12 has good wettability to the molten solder 16. As a result, the molten solder 16 is collected on the pad 12, the gas is collected around the protrusion member 13, and the void 17 is generated around the protrusion member 13. By the surface tension of the molten solder 16, most of the molten solder 16 is collected in a portion indicated by a dotted line in FIG. 9.

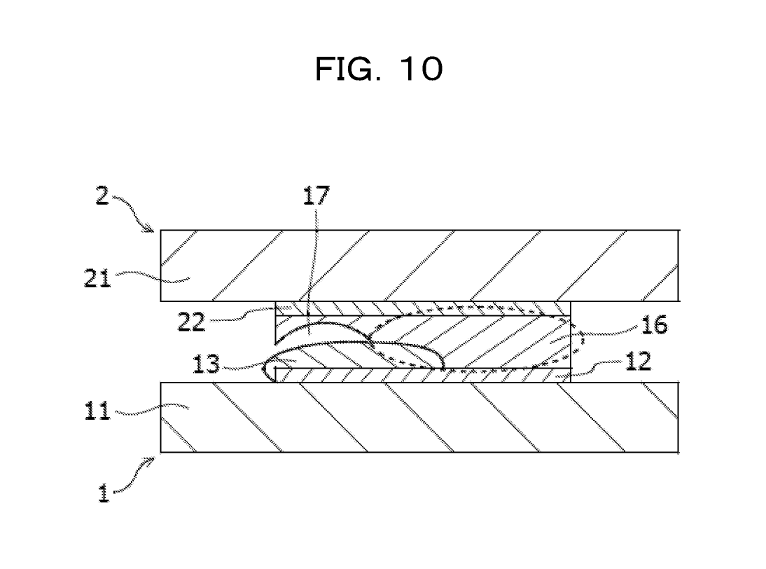

FIG. 10 illustrates a state in the middle of the soldering process (the reflow process). As the molten solder 16 is wetted and spread on the pad 12, the molten solder 16 comes into contact with the protrusion member 13. Due to the weight of the electronic component 2 applied to the molten solder 16 and the surface tension of the molten solder 16, the molten solder 16 is spread over the protrusion member 13 in the state where the molten solder 16 is in contact with the protrusion member 13. As the molten solder 16 is spread over the protrusion member 13, the void 17 generated around the protrusion member 13 is discharged to the outside from the molten solder 16 along the protrusion member 13.

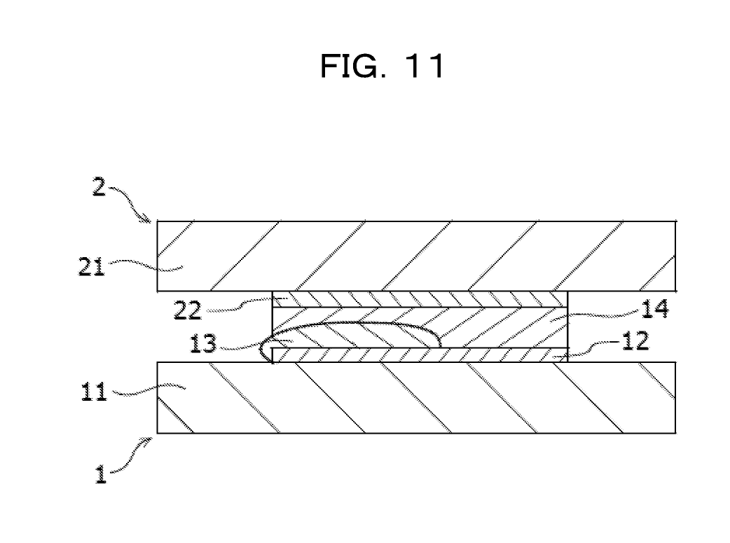

FIG. 11 illustrates the completed state of the soldering process (the reflow process). As the molten solder 17 covers the protrusion member 13 in the state where the molten solder 17 is in contact with the protrusion member 13, the void 17 within the molten solder 16 is discharged to the outside from the molten solder 16 along the protrusion member 13. When the molten solder 16 is cooled to form the solder 14, the generation of void 17 in the solder 14 is suppressed. Also, even in the case where the void 17 within the molten solder 16 is not completely discharged to the outside, the void 17 within the solder 14 becomes smaller. In this way, the protrusion member 13 functions as a control member for the void 17.

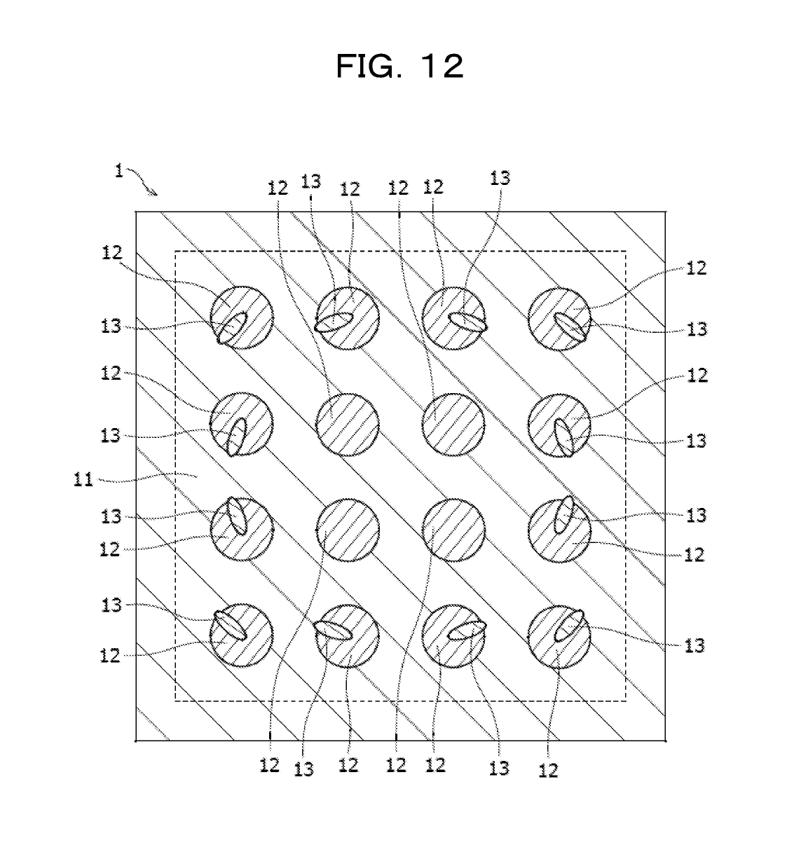

Descriptions will be made on installation directions of protrusion members 13 and presence/absence of installation of the protrusion members 13 with reference to FIG. 12. FIG. 12 is a top view illustrating a portion of the printed circuit board 1. A plurality of pads 12 are formed on the substrate 11. The dotted line in FIG. 12 indicates the appearance of the electronic component 2 (the substrate 21). A plurality of electrodes 22 are arranged in a lattice form on the bottom surface of the substrate 21. The plurality of pads 12 are formed on the positions corresponding to the plurality of electrodes 22 of the electronic component 2, respectively.

The protrusion members 13 are arranged in a direction perpendicular to the direction oriented from the central portion of the electronic component 2 (the substrate 21) towards the outer peripheral portion of the electronic component 2 (the substrate 21). That is, the extension direction of each protrusion member 13 is perpendicular to the direction oriented from the central portion of the electronic component 2 (the substrate 21) towards the peripheral portion of the electronic component 2 (the substrate 21). When the electronic component 2 (substrate 21) has a rectangular appearance when viewed in the plan view, the central portion of the electronic component 2 (the substrate 21) refers to the center of the rectangular shape, or the center of the rectangular shape and a portion around the center. The outer peripheral portion of the electronic component 2 (the substrate 21) refers to the boundary portion between the bottom side and the lateral sides of the electronic component 2 (the substrate 21), or the boundary portion between the bottom side and the lateral sides of the electronic component 2 (the substrate 21) and a portion around the boundary portion.

When a crack occurs in the solder 14 formed between the pad 12 and the electrode 22, the crack in the solder 14 propagates in a direction oriented from the central portion of the electronic component 2 (substrate 21) towards the outer peripheral portion of the electronic component 2 (substrate 21). For example, in the case where the extension direction of a protrusion member 13 is the same as the direction oriented from the central portion of the electronic component 2 (substrate 21) towards the outer peripheral portion of the electronic component 2 (the substrate 21), the crack in the solder 14 is likely to extend along the extension direction of the protrusion member 13. As illustrated in FIG. 12, in the exemplary embodiment, the protrusion members 13 are arranged in the direction perpendicular to the direction oriented from the central portion of the electronic component 2 (substrate 21) towards the outer peripheral portion of the electronic component 2 (the substrate 21), so that the propagation of the crack in the solder 14 may be suppressed.

Each protrusion member 13 may be disposed at a location that has a little influence on the reliability of soldering while avoiding a location at which stresses are expected to be concentrated. As illustrated in FIG. 12, for example, the protrusion member 13 may be disposed at a location corresponding to the outer peripheral portion of the electronic component 2 (the substrate 21), rather than at a location corresponding to the central portion of the electronic component 2 (the substrate 21). Also, in the case where the electronic component 2 is disposed at the central portion of the printed circuit board 1 (the substrate 11), the protrusion member 13 may be disposed in the direction perpendicular to the direction oriented from the central portion of the printed circuit board 1 (the substrate 11) towards the outer peripheral portion of the printed circuit board 1 (the substrate 11).

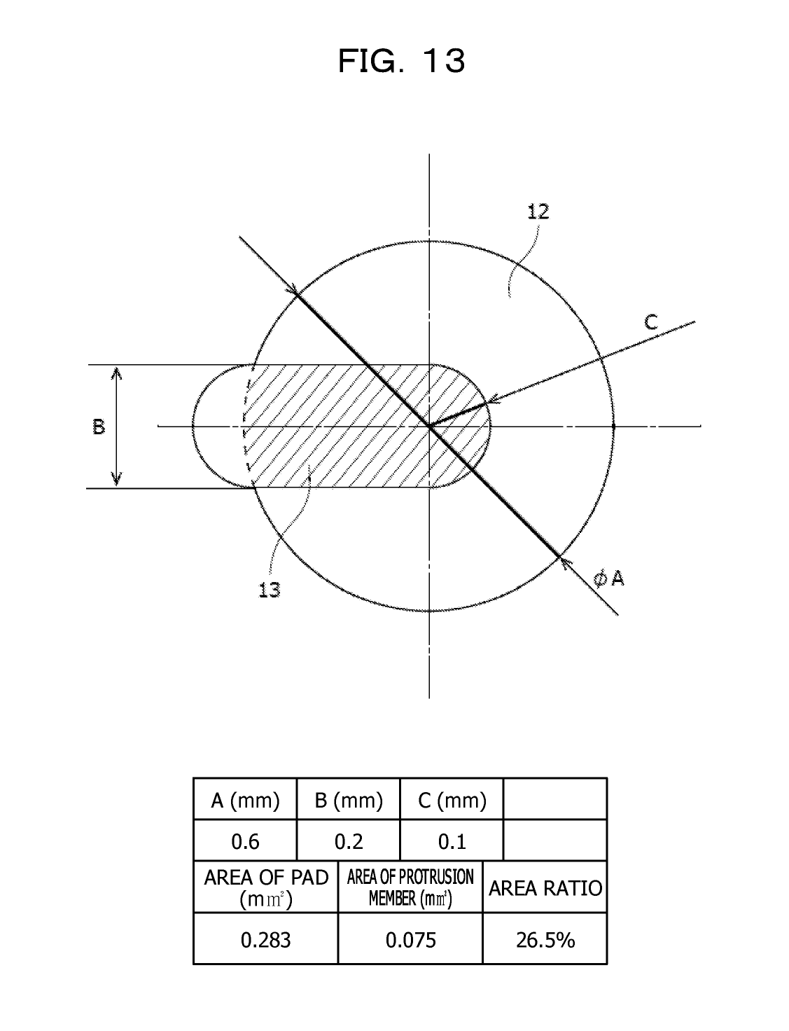

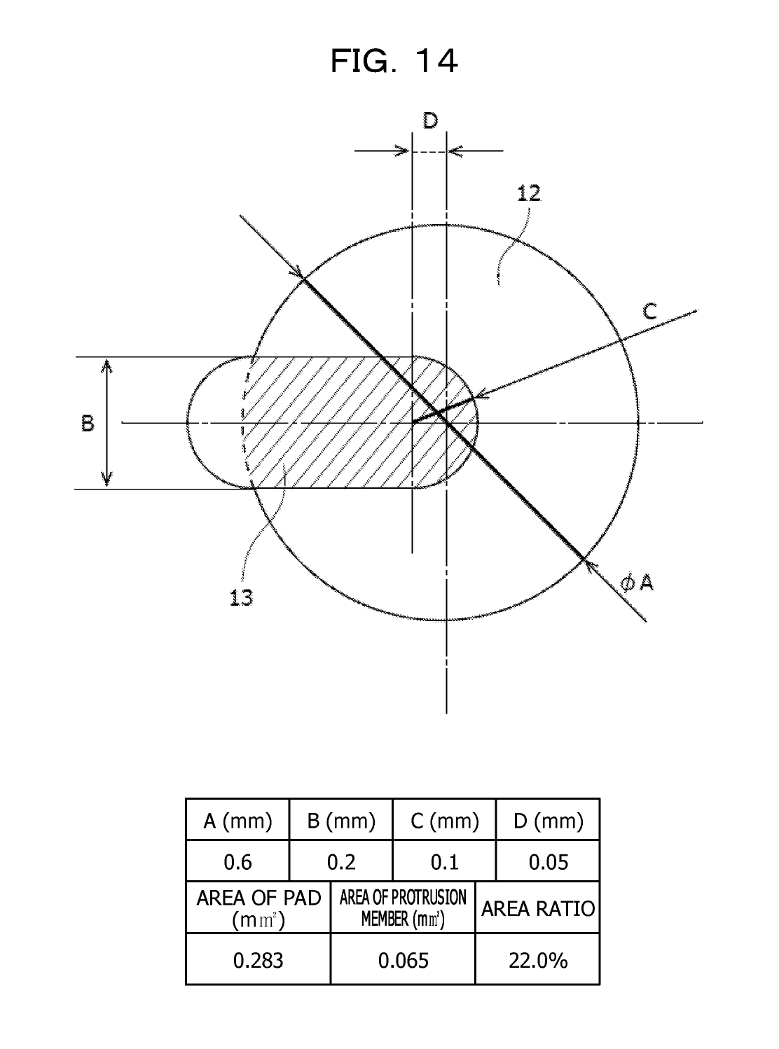

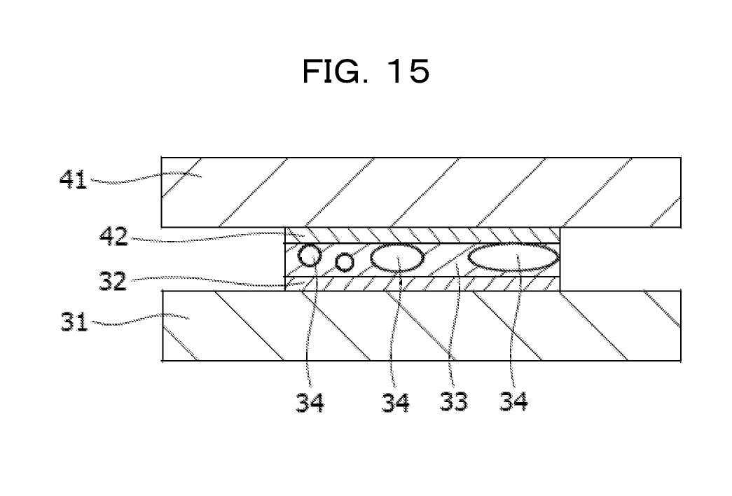

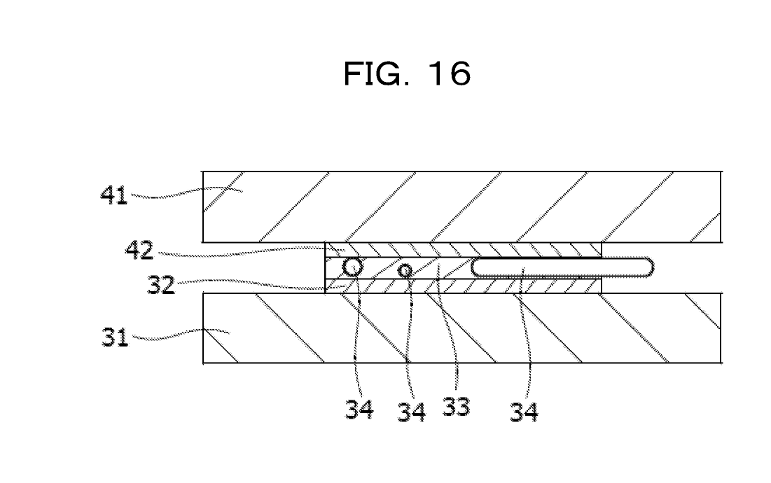

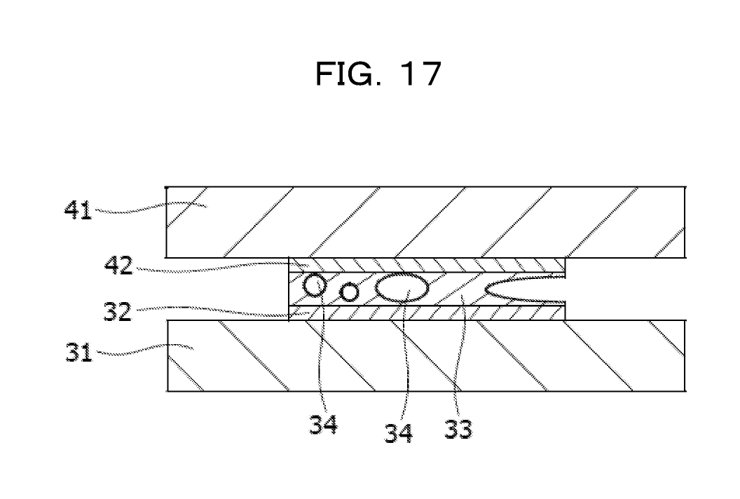

The sizes and areas of the pad 12 and the protrusion member 13 will be described. FIGS. 13 and 14 illustrate exemplary arrangements of the pad 12 and the protrusion member 13. FIGS. 13 and 14 illustrate an appearance of the pad 12 and an appearance of the protrusion member 13 in the plan view. As illustrated in FIGS. 13 and 14, the protrusion member 13 extends from the central portion towards the outer peripheral portion of the pad 12. Compared to the exemplary arrangement illustrated in FIG. 13, the protrusion member 13 in the exemplary arrangement illustrated in FIG. 14 is further shifted from the pad 12.

The respective sizes indicated in FIGS. 13 and 14 are as follows.

A: Diameter of the pad 12 (φ)

B: Width of the protrusion member 13 (shorter direction)

C: Radius of the end of the protrusion member 13

D: Shifted amount of the protrusion member 13

The hatched line portion in FIGS. 13 and 14 indicates a portion where the pad 12 and the protrusion member 13 overlap with each other in the plan view. The area of the pad is a plane area of the pad 12. The area of the protrusion pad is the plane area of the protrusion member 13. The area ratio indicated in FIGS. 13 and 14 refers to an area ratio of the protrusion member 13 which is a ratio of the plane area of the pad 12 in relation to the plane area the protrusion member 13. The IPC-A-610E Standard provides that the total area of voids shall be less than 25% of the area of a pad. Thus, when the area ratio of the protrusion member 13 is set to less than 25%, the IPC-A-610E Standard will be satisfied.

In the exemplary arrangements illustrated in FIGS. 13 and 14, the width of the protrusion member 13 in the shorter direction is ⅓ or less of the diameter (φ) of the pad 12. The shorter direction of the protrusion member 13 is perpendicular to the extension direction of the protrusion member 13. According to the exemplary arrangement illustrated in FIG. 14, the area ratio of the protrusion member 13 is less than 25% and satisfies the IPC-A-610E Standard. When the width of the protrusion member 13 in the shorter direction is set to less than ⅓ of the diameter (φ) of the pad 12, or set to ⅓ or less of the diameter (φ) of the pad 12, the IPC-A-610E Standard is satisfied. Also, without being limited to the exemplary arrangements illustrated in FIGS. 13 and 14, the width of the protrusion member 13 in the shorter direction may be set to ¼ or less, or set to ⅕ or less of the diameter (φ) of the pad 12.

By adjusting the physical properties of a resin used as the material for the protrusion member 13 or the method for applying the resin, the height (thickness) of the protrusion member 13 may be arbitrarily adjusted. As a result of a verification test that was performed under the following conditions, for example, it was observed that a protrusion member 13 having a height of 75 μm was formed and the generation of voids in the solder 14 was suppressed.

Diameter of the pads 12: φ0.6 mm

Pitch of the pads: 12 mm

Method of forming the protrusion members 13: printing method

Thickness of a printing mask: 60 μm

Size of the openings in the mask: 0.4 mm×0.07 mm (width in the longer direction×width in the shorter direction)

Material for the protrusion members 13: Epoxy resin (thermosetting type)

From a demand for high density of electronic components 2 for the printed circuit board 1, it is estimated that the pitch of the pads 12 becomes 0.5 mm or less from 0.8 mm and the diameter of the pads becomes φ0.25 mm or less from φ0.4 mm. According to the present exemplary embodiment, the diameter of the pads 12 may be set to φ0.21 mm and the pitch of the pads 12 may be set to 0.42 mm, As a result, the width of the protrusion members 13 in the shorter direction may become ⅓ of the diameter of the pads 12, and concerning a micro pad (e.g., a pad diameter of less than 0.4 mm), the generation of voids in the solder 14 may also be suppressed.

The thickness (height) of the solder paste may be adjusted depending on the height of the protrusion member 13. Thus, the thickness of the solder paste 15 may be easily increased. When the thickness of the solder paste 15 is thick, the gas within the molten solder 16 may be easily collected around the protrusion member 13 and the gas discharging property may be enhanced. As a result, the generation of voids within the solder 14 may be further suppressed. When the thickness of the solder paste 15 is thin, the gas within the molten solder 16 merely moves horizontally (moves in parallel), and the gas discharging property is poor. When the thickness of the solder paste 15 is thick, the gas within the molten paste 16 may move horizontally (move in parallel) while moving upward, and the gas discharging property is good.

The thickness (height) of the solder 14 may be adjusted depending on the height of the protrusion member 13. Thus, the thickness of the solder 14 may be increased. By increasing the thickness of the solder 14, collapse of the solder 14 may be suppressed and short circuit between adjacent solders may also be suppressed. Therefore, the reliability life of a bonding portion between the printed circuit board 1 and the electronic component 2 may be extended.

In the forgoing, an example of forming the protrusion member 13 on the pad 12 of the substrate 11 has been illustrated. Without being limited to this example, the electronic component 2 may be provided with the protrusion member 13 by forming the protrusion member 13 on the electrode 22 of the substrate 21. Accordingly, the protrusion member 13 is formed on the electrode 22 and extends from the central portion towards the outer peripheral portion of the electrode 22. The solder 14 covers the electrode 22 and the protrusion member 13, and interconnects the pad 12 and the electrode 22. Concerning the installation direction of the protrusion member 13 and presence/absence of installation of the protrusion member 13, this example is the same as the example of installation illustrated in FIG. 12. Since the protrusion member 13 is formed on the electrode 22, the generation of voids within the solder is suppressed when the electronic component 2 is soldered to the printed circuit board 1.

A soldering method in the case where the protrusion member 13 is formed on the electrode 22 will be described. A process for forming the protrusion member 13 on the electrode 22 is the same as the method of forming the protrusion member 13 on the pad 12 (see, e.g., FIG. 6). Next, in the same manner as in the process illustrated in FIG. 7, the solder paste 15 is applied on the electrode 22 and the protrusion member 13 by, for example, the printing method. Subsequently, after aligning the printed circuit board 1 and the electronic component 2, the electronic component 2 is mounted on the substrate 11. As a result, the pad 12 on the printed circuit board 1 comes into contact with the solder paste 15. Next, the solder 14 is formed between the pad 12 and the electrode 22 by performing a reflow process in the same manner as in the process illustrated in FIG. 8, so that the pad 12 and the solder 14 are bonded to each other and the solder 14 and the electrode 22 are bonded to each other. In this case, the substrate 21 is an example of a first substrate, the electrode 22 is an example of a first electrode, the substrate 11 is an example of a second substrate, and the pad 12 is an example of a second electrode.

The electronic component 2 may be a BGA (Ball Grid Array) semiconductor package. In this case, solder balls are formed on the electrode 22 to cover the electrode 22 and the protrusion member 13. When mounting the electronic component 2 on the printed circuit board 1, the generation of voids in the solder balls is suppressed.

For example, there is a method of providing a pair of solder resists on a pad of a substrate, and forming a flow path that communicates with the air by the pad and the solder resists. In this method, however, the diameter of the pad is increased and the flow path is difficult to form on a micro pad. According to the present exemplary embodiment, the protrusion member 13 may be formed on the pad 12 in a process after the solder resists are formed on a portion on the substrate 11, excluding the pad 12. Therefore, in the case where a solder resist is on the substrate, the protrusion member 13 may be formed on the pad 12 and the generation of voids in the solder 14 formed on the pad 12 may be suppressed.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to an illustrating of the superiority and inferiority of the invention. Although the embodiments of the present invention have been described in detail, it should be understood that the various changes, substitutions, and alterations could be made hereto without departing from the spirit and scope of the invention.

What is claimed is:

1. A printed circuit board comprising:
a substrate;
a first electrode formed on the substrate;
a protrusion member formed on the first electrode and extending from a central portion of the first electrode towards an outer peripheral portion of the first electrode; and
a solder covering the first electrode and the protrusion member and connecting the first electrode to a second electrode of a component mounted on the substrate.

2. The printed circuit board according to claim 1, wherein an extension direction of the protrusion member is perpendicular to a direction oriented from a central portion of the component towards an outer peripheral portion of the component.

3. The printed circuit board according to claim 1, wherein the protrusion member has a width in a shorter direction which is ⅓ or less of a diameter of the first electrode.

4. The printed circuit board according to claim 1, wherein the first electrode is bonded to the solder and the protrusion member is in contact with the solder.

5. A soldering method comprising:
forming a protrusion member on a first electrode formed on a first substrate, the protrusion member extending from a central portion of the first electrode towards an outer peripheral portion of the first electrode;
applying a solder paste to cover the first electrode and the protrusion member;
causing a second electrode formed on a second substrate arranged opposite to the first electrode to come in contact with the solder paste; and
soldering the first electrode and the second electrode by performing heating and cooling.

6. The method according to claim 5, wherein an extension direction of the protrusion member is perpendicular to a direction oriented from the central portion of the first substrate or the second substrate towards the outer peripheral portion of the first substrate or the second substrate.

7. The method according to claim 5, wherein the protrusion member has a diameter in a shorter direction which is ⅓ or less of a diameter of the first electrode.

8. The method according to claim 5, wherein the first electrode is bonded to the solder and the protrusion member is in contact with the solder.
